(19) United States
(12) Patent Application Publication
(10) Pub. No.: US 2016/0372920 A1
(43) Pub. Date: Dec. 22, 2016

(54) INTEGRATED ESD PROTECTION CIRCUITS IN GAN

(71) Applicant: NAVITAS SEMICONDUCTOR, INC., El Segundo, CA (US)

(72) Inventors: Daniel M. Kinzer, El Segundo, CA (US); Santosh Sharma, Monterey Park, CA (US); Jason Zhang, Monterey Park, CA (US); Marco Giandalia, Marina Del Rey, CA (US)

(21) Appl. No.: 14/743,815

(22) Filed: Jun. 18, 2015

(51) Int. Cl. H02H 9/04; H01L 27/02

(52) U.S. Cl. CPC H02H 9/046; H01L 27/0266

(57) ABSTRACT

An electronic circuit is disclosed and described herein. The circuit includes first and second pins, and an overvoltage protection circuit including a first enhancement-mode transistor. The overvoltage protection circuit is disposed on a GaN-based substrate, and the first enhancement mode transistor is configured to provide overvoltage protection between the first and second pins.

### FIELD OF THE INVENTION

The present disclosure relates generally to electrostatic discharge (ESD) circuits and more specifically to ESD circuits integrated with other circuits on a GaN or similar substrate.

### BACKGROUND OF THE INVENTION

Electronic devices such as computers, servers, and televisions, among others, may use one or more integrated circuits to function. The integrated circuits may, for example, be implemented in a GaN (or similar) technology and are susceptible to damage caused by ESD events or overvoltage events. ESD and overvoltage protection circuitry which can be integrated in the integrated circuits is needed.

ESD and overvoltage protection strategies in GaN technologies presents particular difficulties. For example, bipolar devices which are typically used in silicon such as diodes/BJTs or SCRs are extremely hard to manufacture in GaN because of the extremely difficult nature of implanting dopant impurities into GaN substrates and activating them to make rectifying junctions.

ESD and overvoltage protection circuits should also not interfere with circuit functionality during normal operation. This means the ESD and overvoltage protection circuits should not contribute in any significant manner to the current leakage at the pin that it is connected to. Also the ESD and overvoltage protection circuits should not be activated during normal device operation. If not prevented, such activation could result in shoot-through current from the pin to ground or power. ESD and overvoltage protection circuits should also have a reasonable ESD and overvoltage performance for both positive and negative ESD and overvoltage events.

### SUMMARY OF THE INVENTION

One inventive aspect is a circuit. The circuit includes first and second pins, and an overvoltage protection circuit including a first enhancement-mode transistor. The overvoltage protection circuit is disposed on a GaN-based substrate, and the first enhancement mode transistor is configured to provide overvoltage protection between the first and second pins.

Another inventive aspect is an electronic power conversion component. The component includes a package base, and one or more GaN-based dies secured to the package base. The GaN-based die includes a first circuit with at least one enhancement-mode transistor, and an overvoltage protection circuit coupled to the first circuit.

Another inventive aspect is a method of operating a GaN-based circuit. The method includes receiving a voltage greater than a threshold across two pins of the circuit, and in response to the received voltage, turning on a GaN-based enhancement-mode transistor coupled between the two pins, such that the enhancement-mode transistor conducts current between the two pins while the voltage potential is greater than the threshold.

### BRIEF DESCRIPTION OF THE DRAWINGS

FIG. 1 is a schematic illustration of a protection circuit.

FIG. 2 is a schematic illustration of a protection circuit.

FIG. 3 is a schematic illustration of a protection circuit.

FIG. 4 is a schematic illustration of an embodiment of a protection circuit.

FIG. 5 is a schematic illustration of an embodiment of a protection circuit.

FIG. 6 is an alternative embodiment of a protection circuit.

FIG. 7 is a schematic illustration of an embodiment of a protection circuit.

FIG. 8 is a schematic illustration of an embodiment of a protection circuit.

FIG. 9 is a generalized schematic illustration of an embodiment of a protection circuit.

FIG. 10 is a generalized schematic illustration of an embodiment of a protection circuit.

FIG. 11 is a schematic illustration of an embodiment of a protection off circuit.

FIG. 12 is a schematic illustration of an embodiment of an inverter.

FIG. 13 is a schematic illustration of protection circuit.

FIG. 14 is a schematic illustration of an ESD protection circuit.

### DETAILED DESCRIPTION OF THE INVENTION

FIG. 1 is a schematic illustration of a protection circuit 10. Protection circuit 10 includes one or more GaN transistors formed on a GaN substrate and is integrated on the GaN substrate with GaN internal circuitry 20. In some embodiments, protection circuit 10 and internal circuitry 20 are on a GaN-based die secured to a package base of an electronic power conversion component. In some embodiments, the component includes multiple GaN-based die secured to the package base.

In addition, protection circuit 10 is configured to conditionally conduct current between Pin 1 and Pin 2. In some embodiments, Pin 1 and Pin 2 are connected to or are external terminals of a packaged device. The current conducted between Pin 1 and Pin 2 limits the voltage difference between Pin 1 and Pin 2, which, if not limited, would otherwise damage internal circuitry 20. Therefore, protection circuit 10 conducts current during, for example, an ESD event or an overvoltage event to protect internal circuitry 20. In some embodiments, protection circuit 10 remains off or nonconductive unless the voltage difference between Pin 1 and Pin 2 is greater than a threshold.

In some embodiments, protection circuit 10 is unidirectional. For example, protection circuit 10 may be configured to conduct current from Pin 1 to Pin 2 in response to the voltage at Pin 1 being greater than the voltage at Pin 2. In some embodiments, protection circuit 10 may be configured to not conduct current from Pin 2 to Pin 1 in response to the voltage at Pin 2 being greater than the voltage at Pin 1.

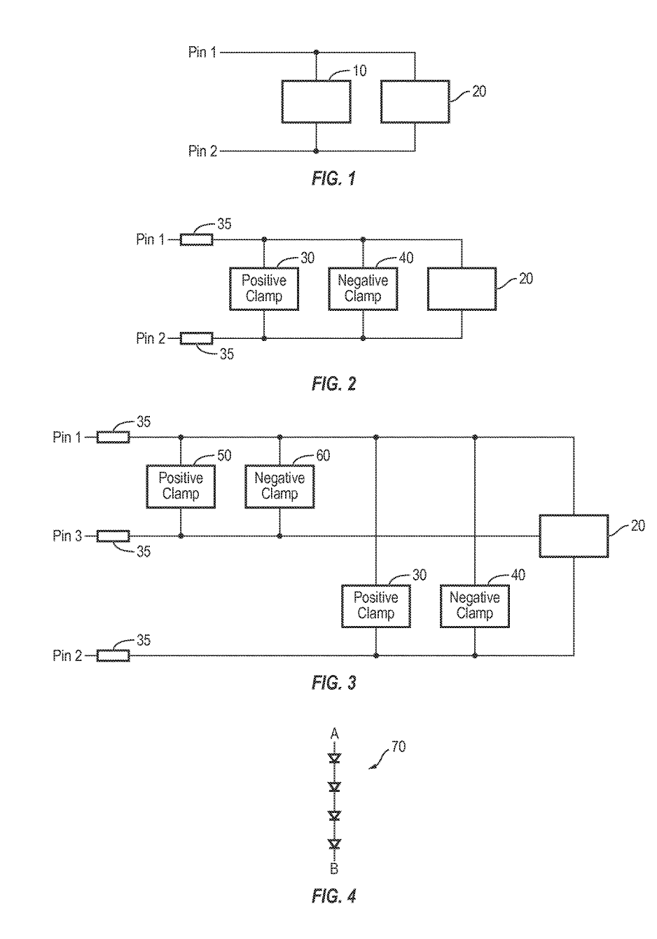

FIG. 2 is a schematic illustration of a protection circuit which includes unidirectional protection circuits 30 and 40. Protection circuits 30 and 40 each include one or more GaN transistors formed on a GaN substrate and are integrated on the GaN substrate with GaN internal circuitry 20. In some embodiments, protection circuits 30 and 40 are oppositely oriented. For example, in this embodiment, protection circuit 30 is oriented so as to conduct current from Pin 1 to Pin 2 in response to the voltage at Pin 1 being greater than the voltage at Pin 2, and protection circuit 40 is oriented so as to conduct current from Pin 2 to Pin 1 in response to the voltage at Pin 2 being greater than the voltage at Pin 1. In some embodiments, protection circuits 30 and 40 remain off or nonconductive unless the voltage difference between Pin 1 and Pin 2 is greater than a threshold.

The protection circuit of FIG. 2 also includes optional current limiting elements 35. In some embodiments, current limiting elements 35 are omitted.

Current limiting elements 35 may, for example, comprise one or more depletion mode devices or 2D electron gas resistors constructed, for example, in an AlGaN/GaN HEMT technology. Current limiting elements 35 may exhibit saturating characteristics.

As is understood in the art, for depletion mode transistors, the saturation current may, for example, be a function of the channel length and width. In addition, the saturation voltage for depletion mode transistors (voltage at which current reaches saturation) is a function of the channel length.

In the case of a 2D electron gas resistor, as is understood in the art, the saturation current may be a function of the distance between two ohmic contacts and the width of the 2D electron gas resistor. In addition, the saturation voltage may be a function of the distance between the two ohmic contacts.

As an example, if the saturation voltage of the current limiting element is about 10V, and the saturation current through the current limiting element is about 3 mA, when an ESD pulse of >1 kV appears at the pin connected to the current limiting element, the voltage across the current limiting element will quickly exceed the saturation voltage (10V) and will result in the ESD current through the current limiting element saturating at 3 mA. As a result, only 3 mA will be conducted by the protection circuit. Most of the ESD voltage (>1 kV in this example) will drop across the current limiting element. As a result, the protection circuit can be sized down so as to have a current conducting capacity related to the saturation current of the current limiting element.

Accordingly, protection circuits 30 and 40 provide internal circuitry 20 symmetric protection from at least one of an ESD event and an overvoltage event either causing the voltage at Pin 1 to be greater than the voltage at Pin 2 or causing the voltage at Pin 2 to be greater than the voltage at Pin 1.

FIG. 3 is a schematic illustration of a protection circuit which includes unidirectional protection circuits 30, 40, 50, 60. Protection circuits 30, 40, 50, and 50 each include one or more GaN transistors formed on a GaN substrate and are integrated on the GaN substrate with GaN internal circuitry 20.

In some embodiments, protection circuits 30 and 40 are oppositely oriented, and protection circuits 50 and 60 are oppositely oriented. For example, in this embodiment, protection circuit 30 is oriented so as to conduct current from Pin 1 to Pin 2 in response to the voltage at Pin 1 being greater than the voltage at Pin 2, and protection circuit 40 is oriented so as to conduct current from Pin 2 to Pin 1 in response to the voltage at Pin 2 being greater than the voltage at Pin 1. In addition, in this embodiment, protection circuit 50 is oriented so as to conduct current from Pin 1 to Pin 3 in response to the voltage at Pin 1 being greater than the voltage at Pin 3, and protection circuit 60 is oriented so as to conduct current from Pin 3 to Pin 1 in response to the voltage at Pin 3 being greater than the voltage at Pin 1.

As a result, protection circuits 30, 40, 50, and 60 provide internal circuitry 20 symmetric protection from at least one of an ESD event and an overvoltage event either causing the voltage at any of Pins 1, 2, and 3 to be greater than the voltage at either of the other two pins.

Any of Pins 1, 2, and 3 of FIGS. 1, 2, and 3 may be, for example, a power pin, such as a conductor connected to a power or ground source. Any of Pins 1, 2, and 3 may be, for example, an input pin, an output pin, an input/output pin, or any other type of pin.

Protection circuits 10, 30, 40, 50, and 60 may, for example, be configured to conduct at least 100 mA, 250 mA, 500 mA, 1A, 2A, or 5A.

Internal circuitry 20 of FIGS. 1, 2, and 3 may include a power transistor. For example, internal circuitry 20 may include a power transistor having its gate connected to a first pin of Pins 1, 2, and 3 and its source connected to a second, different pin of Pins 1, 2, and 3.

FIG. 4 is a schematic illustration of an embodiment of a protection circuit 70, which may, for example, be used in protection circuits 10, 30, 40, 50, and 60 discussed with reference to FIGS. 1, 2, and 3.

Protection circuit 70 includes multiple diodes. In some embodiments, similar protection circuits include a single diode. In response to a voltage at node A being greater than the sum of the voltage thresholds of the diodes higher than the voltage at node B, the diodes will conduct current from node A to node B. The current conduction will tend to limit (or clamp) the voltage difference between nodes A and B.

One or more of the diodes may be Schottky diodes. Alternatively or additionally, one or more of the diodes may be diode connected enhancement mode or depletion mode GaN transistors. The number of diodes or diode connected transistors may be varied.

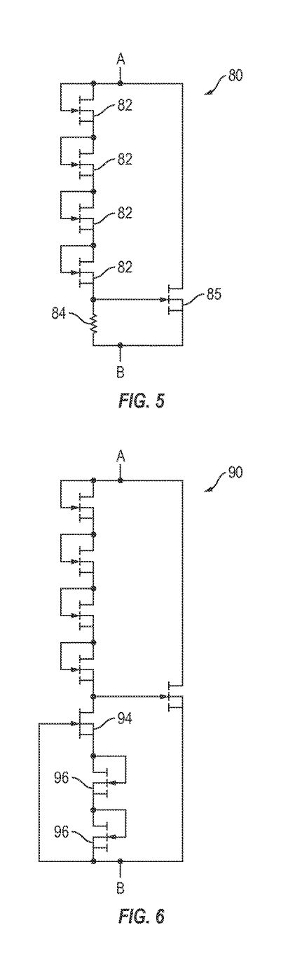

FIG. 5 is a schematic illustration of an embodiment of a protection circuit 80, which may, for example, be used in protection circuits 10, 30, 40, 50, and 60 discussed with reference to FIGS. 1, 2, and 3.

Protection circuit 80 includes one or more diode connected enhancement mode GaN transistors 82 connected in series with resistor 84 between nodes A and B. Protection circuit 80 also includes an enhancement mode GaN transistor 85 connected between nodes A and B. As shown, protection circuit 80 does not include depletion mode transistors.

In response to a voltage at node A being greater than the sum of the voltage thresholds of the diode connected transistors 82 higher than the voltage at node B, the diode connected transistors 82 conduct current from node A to node B through resistor 84, causing the gate voltage of the enhancement mode GaN transistor 85 to rise. In response to its gate voltage rising, enhancement mode GaN transistor 85 also conducts current from node A to node B, clamping the voltage difference between nodes A and B to be about equal to the sum of the voltage thresholds of the transistors 82.

In this embodiment, the voltage threshold for causing protection circuit 80 to conduct is determined by the number of diode connected enhancement mode GaN transistors 82 and their voltage thresholds. However, the current carrying capacity of the diode connected enhancement mode GaN transistors 82 need not be sufficient to conduct the current needed to limit the voltage difference across nodes A and B. Instead, enhancement mode GaN transistor 85 is configured to conduct current sufficient to limit the voltage difference across nodes A and B.

In some embodiments, one or more of the diodes 82 may be Schottky diodes. The number of diodes or diode connected transistors may be varied.

In some embodiments, the resistor 84 is formed or replaced by: a) one or more diode connected enhancement mode GaN transistors, b) one or more depletion mode GaN transistors having their gates connected to either their sources or to node B, or c) one or more current sources.

In some embodiments, the resistor 84 is formed or replaced by a combination of: a) one or more diode connected enhancement mode GaN transistors, b) one or more depletion mode GaN transistors having their gates connected to either their sources or to node B, and c) one or more current sources.

For example, FIG. 6 is an alternative embodiment of a protection circuit 90, which may, for example, be used in protection circuits 10, 30, 40, 50, and 60 discussed with reference to FIGS. 1, 2, and 3. In protection circuit 90, the resistor 84 of protection circuit 80 has been replaced with depletion mode GaN transistor 94, which is cascoded with diode connected enhancement mode GaN transistors 96.

FIG. 7 is a schematic illustration of an embodiment of a protection circuit 100, which may, for example, be used in protection circuits 10, 30, 40, 50, and 60 discussed with reference to FIGS. 1, 2, and 3.

Protection circuit 100 includes one or more diode connected enhancement mode GaN transistors 102 connected with resistors 104 between nodes A and B. Protection circuit 100 also includes an enhancement mode GaN transistor 105 connected between nodes A and B. As shown, protection circuit 100 does not include depletion mode transistors.

In response to a voltage at node A being greater than the voltage threshold of the transistor 102-1 higher than the voltage at node B, the transistor 102-1 conducts current from node A to node B through resistor 104-1, causing the gate voltage of the transistor 102-2 to rise.

In response to the gate voltage of the transistor 102-2 being greater than the voltage threshold of the transistor 102-2 higher than the voltage at node B, the transistor 102-2 conducts current from node A to node B through resistor 104-2, causing the gate voltage of the transistor 102-3 to rise.

In response to the gate voltage of the transistor 102-3 being greater than the voltage threshold of the transistor 102-3 higher than the voltage at node B, the transistor 102-3 conducts current from node A to node B through resistor 104-3, causing the gate voltage of the transistor 102-4 to rise.

In response to the gate voltage of the transistor 102-4 being greater than the voltage threshold of the transistor 102-4 higher than the voltage at node B, the transistor 102-4 conducts current from node A to node B through resistor 104-4, causing the gate voltage of the transistor 105 to rise.

In response to its gate voltage rising, transistor 105 also conducts current from node A to node B. Accordingly, in response to the voltage at node A being greater than the sum of the voltage thresholds of the transistors 102 and 105 higher than the voltage at node B, the transistor 105 conducts current from node A to node B, clamping the voltage difference between nodes A and B to be about equal to the sum of the voltage thresholds of the transistors 102 and 105.

In this embodiment, the voltage threshold for causing protection circuit 100 to conduct is partly determined by the number of transistors 102 and their voltage thresholds. However, the current carrying capacity of the diode connected enhancement mode GaN transistors 102 need not be sufficient to conduct the current needed to limit the voltage difference across nodes A and B. Instead, enhancement mode GaN transistor 105 is configured to conduct additional current sufficient to limit the voltage difference across nodes A and B.

In some embodiments, transistor 102-1 may be a Schottky diode. The number of diode connected transistors may be varied.

In some embodiments, the resistors 104 are formed or replaced by: a) one or more diode connected enhancement mode GaN transistors, b) one or more depletion mode GaN transistors having their gates connected to either their sources or to node B, or c) one or more current sources.

In some embodiments, the resistors 104 are formed or replaced by a combination of: a) one or more diode connected enhancement mode GaN transistors, b) one or more depletion mode GaN transistors having their gates connected to either their sources or to node B, and c) one or more current sources.

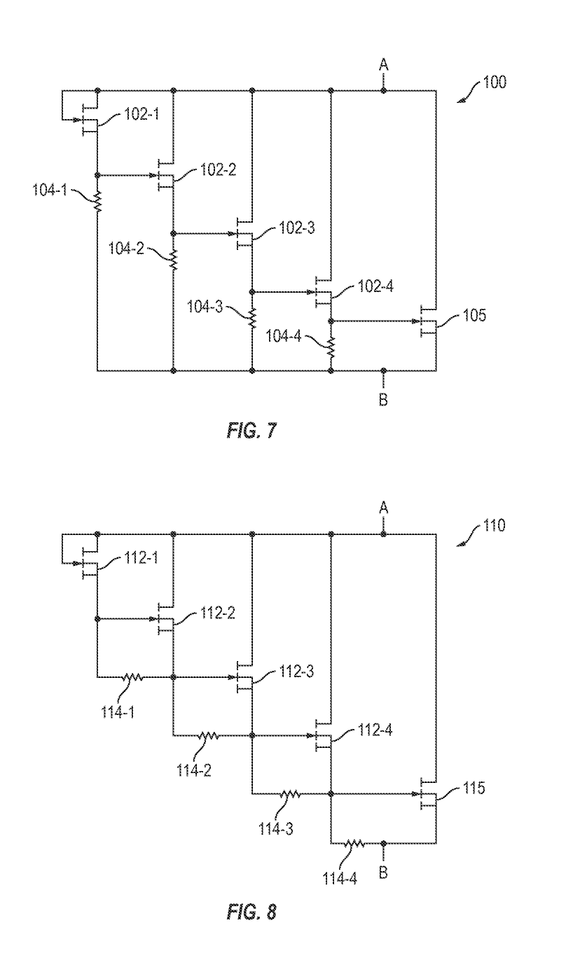

FIG. 8 is a schematic illustration of an embodiment of a protection circuit 110, which may, for example, be used in protection circuits 10, 30, 40, 50, and 60 discussed with reference to FIGS. 1, 2, and 3.

Protection circuit 110 includes one or more diode connected enhancement mode GaN transistors 112 connected with resistors 114 between nodes A and B. Protection circuit 110 also includes an enhancement mode GaN transistor 115 connected between nodes A and B. As shown, protection circuit 110 does not include depletion mode transistors.

In response to a voltage at node A being greater than the voltage threshold of the transistor 112-1 higher than the voltage at node B, the transistor 112-1 conducts current from node A to node B through resistors 104, causing the source and gate voltages of the transistor 122-2 to rise.

In response to the gate voltage of the transistor 112-2 being greater than the voltage threshold of the transistor 112-2 higher than its source voltage, the transistor 112-2 conducts current from node A to node B through resistors 114-2, 114-3, and 114-4, causing the source and gate voltages of the transistor 112-3 to rise.

In response to the gate voltage of the transistor 112-3 being greater than the voltage threshold of the transistor 112-3 higher than its source voltage, the transistor 112-3 conducts current from node A to node B through resistors 114-3 and 114-4, causing the source and gate voltages of the transistor 112-4 to rise.

In response to the gate voltage of the transistor 112-4 being greater than the voltage threshold of the transistor 112-4 higher than its source voltage, the transistor 112-4 conducts current from node A to node B through resistor 114-4, causing the gate voltage of the transistor 115 to rise.

In response to its gate voltage rising, transistor 115 also conducts current from node A to node B. Accordingly, in response to the voltage at node A being greater than the sum of the voltage thresholds of the transistors 112 and 115 higher than the voltage at node B, the transistor 115 conducts current from node A to node B, clamping the voltage difference between nodes A and B to be about equal to the sum of the voltage thresholds of the transistors 112 and 115.

In this embodiment, the voltage threshold for causing protection circuit 110 to conduct is determined partly by the number of transistors 112 and their voltage thresholds. However, the current carrying capacity of the diode connected enhancement mode GaN transistors 112 need not be sufficient to conduct the current needed to limit the voltage difference across nodes A and B. Instead, enhancement mode GaN transistor 115 is configured to conduct additional current sufficient to limit the voltage difference across nodes A and B.

In some embodiments, transistor 112-1 may be a Schottky diode. The number of diode connected transistors may be varied.

In some embodiments, the resistors 114 are formed or replaced by: a) one or more diode connected enhancement mode GaN transistors, b) one or more depletion mode GaN transistors having their gates connected to either their sources or to node B, or c) one or more current sources.

In some embodiments, the resistors 114 are formed or replaced by a combination of: a) one or more diode connected enhancement mode GaN transistors, b) one or more depletion mode GaN transistors having their gates connected to either their sources or to node B, and c) one or more current sources.

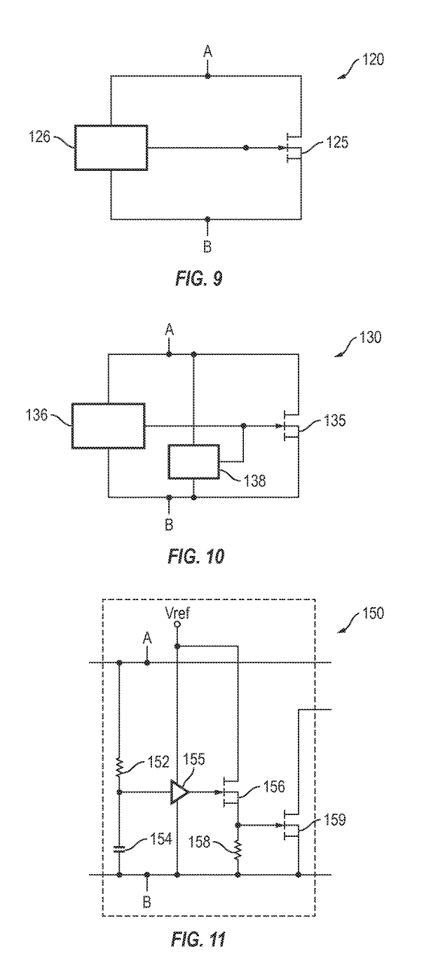

FIG. 9 is a generalized schematic illustration of an embodiment of a protection circuit 120, which may, for example, be used in protection circuits 10, 30, 40, 50, and 60 discussed with reference to FIGS. 1, 2, and 3.

Protection circuit 120 includes an enhancement mode GaN ESD transistor 125 connected between nodes A and B. In addition, protection circuit 120 includes gate control circuit 126. In this embodiment, gate control circuit 126 is configured to control the gate voltage of ESD transistor 125. Embodiments of gate control circuit 126 are illustrated in FIGS. 5, 6, 7, and 8, and each of the gate control circuits of FIGS. 5, 6, 7, and 8 respectively control the gate of the ESD transistor connected thereto.

As discussed above, turning on an ESD transistor during an ESD event is particularly beneficial to prevent damage of circuitry. During normal operation, however, turning on the ESD transistor would be problematic.

FIG. 10 is a generalized schematic illustration of an embodiment of a protection circuit 130, which may, for example, be used in protection circuits 10, 30, 40, 50, and 60 discussed with reference to FIGS. 1, 2, and 3.

Protection circuit 130 includes an enhancement mode GaN ESD transistor 135 connected between nodes A and B. In addition, protection circuit 130 includes gate control circuit 136, which is configured to control the gate voltage of ESD transistor 135. Gate control circuit 136 may have features similar or identical to the other gate control circuits discussed herein. Protection circuit 130 also includes protection off circuit 138.

Protection off circuit 138 is configured to conditionally prevent the voltage at the gate of ESD transistor 135 from being driven high enough by control circuit 136 to turn on ESD transistor 135. For example, protection off circuit 138 may be configured to prevent ESD transistor 135 from turning on during normal operation, and may be further configured to allow ESD transistor 135 to turn on during ESD or overvoltage events.

FIG. 11 is a schematic illustration of an embodiment of a protection off circuit 150. Protection off circuit 150 includes Rlpf 152, Clpf 154, input slew rate dependent buffer 155, level shift GaN transistor 156, level shift resistor 158, and pulldown GaN transistor 159.

In this embodiment, Rlpf 152 and Clpf 154 collectively form a low pass filter providing an output to buffer 155 based on the voltages at nodes A and B. Other low pass filter architectures may alternatively be used.

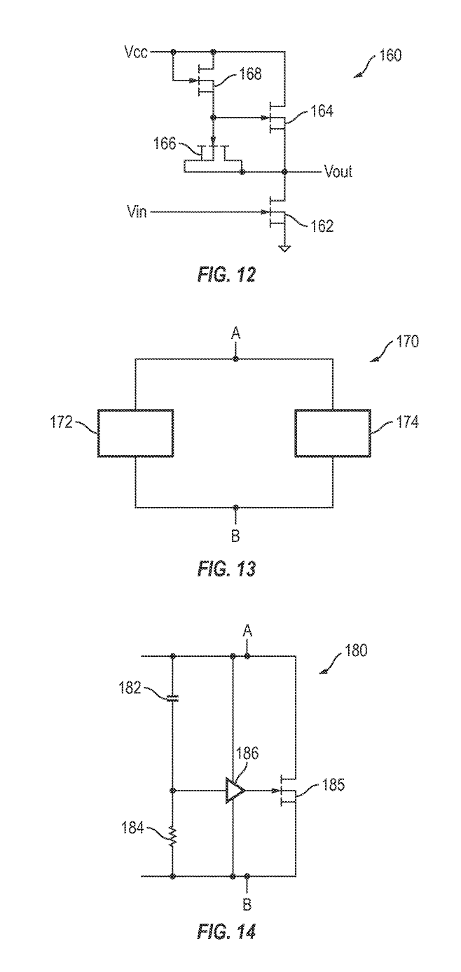

Input slew rate dependent buffer 155 provides an output based on the voltage at its input and at least partly based on the slew rate of the voltage at its input. An embodiment is discussed below with reference to FIG. 12. Additional alternative embodiments are discussed in co-owned U.S. application Ser. No. 14/737,259, filed Jun. 11, 2015, and entitled “GaN CIRCUIT DRIVERS FOR GaN CIRCUIT LOADS,” which is incorporated herein by reference.

In this embodiment, level shift GaN transistor 156 and level shift resistor 158 cooperatively form a level shifter configured to shift the output voltage from the buffer 155 down by the threshold voltage of transistor 156 to drive the gate of pulldown GaN transistor 159.

While turned on, pulldown transistor 159 conducts current from the output node (connected to the gate of an ESD transistor) to node B, to prevent the ESD transistor from turning on.

This may be useful, for example, to prevent the ESD transistor from turning on during normal operation. For example, during normal operation, the voltage difference between nodes A and B changes. If the difference changes from a low voltage value to a high voltage value, without the ESD protection off circuit, a gate control circuit may turn on or may slightly turn on the ESD transistor. To prevent this, the low pass filter of ESD protection off circuit 150 generates a rising signal at the input of input slew rate dependent buffer 155. The slew rate of the rising signal is great enough that the output of buffer 155 is at or near Vref. The output of the buffer 155 is level shifted by the level shifter, and the pulldown transistor 159 turns on. As a result, the ESD transistor connected to pulldown transistor 159 may not be turned on by the gate control circuit during normal operation.

ESD events generally cause large voltage differences for a short time. Therefore, an ESD event between nodes A and B causes a large voltage difference between the voltages at nodes A and B for a short time.

The low pass filter of protection off circuit 150 attenuates the ESD signal such that the buffer 155 does not receive an input high enough to generate an output which would result in transistor 159 turning on. As a result, despite its high voltage, an ESD event does not cause the protection off circuit 150 to prevent an ESD transistor connected thereto from turning on. Accordingly, the ESD protection transistor functions to protect the device from the ESD event.

An overvoltage condition includes a voltage difference between nodes A and B which is greater than typical use conditions for duration which is typically greater than that of an ESD event. Such overvoltage conditions can also damage internal circuitry, and are preferably managed by turning on the ESD protection transistor.

During an overvoltage condition, the output of the low pass filter rises with a slew rate which is not great enough to cause the input slew rate dependent buffer 155 to output a voltage at or near Vref. Instead, the output of buffer 155 may, for example, be near Vref/2. The output of the buffer 155 is level shifted by the level shifter, and because its gate is not sufficiently high, the pulldown transistor 159 does not turn on. Therefore, an ESD transistor connected to pulldown transistor 159 may be turned on. Accordingly, for an overvoltage condition, a gate control circuit connected to the ESD transistor may turn on the ESD transistor in response to the overvoltage condition.

In some embodiments, a level shifter circuit is not used.

FIG. 12 is a schematic illustration of an embodiment of an inverter 160, which may be connected to a second inverter to form the slew rate dependent buffer 155 of FIG. 11. As shown, inverter 160 includes pulldown transistor 162, which receives an input to the inverter 160 at its gate. In addition, inverter 160 includes pull-up transistor 164. Furthermore, inverter 160 includes control circuitry comprising capacitor 166 and diode 168. The output node of the inverter 160 is connected to pulldown transistor 162, pull-up transistor 164, and capacitor 166.

In the inverter 160, when Vin is ramped up to a voltage greater than the threshold voltage (Vth) of the pulldown transistor 162 the pulldown transistor 162 turns on. This causes the output voltage to be driven to ground, and charges the capacitor 166 through the diode 168 to a voltage equal to Vcc−Vth. The voltage at the gate of the transistor 164 is equal to Vcc−Vth, which is enough to just turn on the pull-up transistor 164, but the pull-up transistor 164 is sized so that it does not pull the output high with pulldown transistor 162 conducting.

When Vin is ramped below Vth the pulldown transistor 162 is turned off. This causes the output voltage to rise towards Vcc, since the pull-up transistor 164 is still conducting. This will cause a positive going dv/dt at the bottom plate of the capacitor 166. As a result of charge injection, dv/dt at the top plate of the capacitor 166 will also occur. If the capacitor 166 has sufficiently large capacitance as compared with the other capacitances at the top plate, the dv/dt at the top plate of the capacitor 166 will be similar to the dv/dt at the bottom plate of the capacitor 166. The positive going dv/dt at the top plate of the capacitor 166 will increase the gate voltage of the pull-up transistor 164, for example, to a voltage at least greater than a threshold voltage above Vcc. This results in the positive going dv/dt at the output node. The output voltage is ramped up to a voltage close to or equal to Vcc. The diode 168 is reverse biased during this period and will not allow discharge of the capacitor voltage.

When Vin is ramped below Vth with a dv/dt which is slow, the pulldown transistor 162 is slowly turned off. This causes the output voltage to rise towards Vcc slowly, generating a slow positive going dv/dt at the bottom plate of the capacitor 166. As a result of the slow dv/dt at the bottom plate, the dv/dt at the top plate of the capacitor 166 will also be slow at least because of charge leakage. The slow positive going dv/dt at the top plate of the capacitor 166 may not substantially increase the gate voltage of the pull-up transistor 164. This results in the gate voltage of the pull-up transistor 164 substantially remaining at Vcc−Vt. The output voltage is therefore ramped up to a voltage close to or equal to Vcc−2Vt.

Accordingly, the high output of inverter 160 is dependent on the input slew rate of high to low voltage transitions. For transitions greater than a threshold, the high output of inverter 160 is substantially equal to Vcc. For transitions less than the threshold, the high output of inverter 160 is less than Vcc. For transitions less than a second threshold, the high output of inverter 160 is substantially equal to Vcc−2Vth.

FIG. 13 is a schematic illustration of protection circuit 170. Protection circuit 170 includes overvoltage protection circuit 172 and ESD protection circuit 174.

Overvoltage protection circuit 172 is configured to prevent damage caused by an overvoltage condition. Overvoltage protection circuit 172 may have features similar or identical to the protection circuits discussed elsewhere herein. Overvoltage protection circuit 172 may be designed so as to cause current to conduct between nodes A and B for overvoltage conditions lasting greater than a minimum duration or beginning with a slew rate less than a threshold, and to not conduct current between nodes A and B for low voltage conditions or for overvoltage conditions lasting less than a duration or beginning with a slew rate greater than a threshold.

ESD protection circuit 174 is configured to prevent damage caused by an ESD event. ESD protection circuit 174 may have features similar or identical to the protection circuits discussed elsewhere herein. ESD protection circuit 174 may be designed so as to cause current to conduct between nodes A and B for ESD or overvoltage events beginning with a slew rate greater than a threshold, and to not conduct current between nodes A and B for low voltage conditions or for overvoltage conditions beginning with a slew rate less than a threshold.

FIG. 14 is a schematic illustration of an ESD protection circuit 180 configured to cause current to conduct between nodes A and B for ESD or overvoltage events beginning with a slew rate greater than a threshold, and to not conduct current between nodes A and B for low voltage conditions or for overvoltage conditions beginning with a slew rate less than a threshold.

ESD protection circuit 180 includes Chpf 182, Rhpf 184, input slew rate dependent buffer 186, and ESD GaN transistor 185.

In this embodiment, Chpf 182 and Rhpf 184 collectively form a high pass filter providing an output to buffer 186 based on the voltages at nodes A and B. Other high pass filter architectures may alternatively be used.

Input slew rate dependent buffer 186 generates an output based on the voltage at its input and at least partly based on the slew rate of the voltage at its input, and may, for example, be similar to Input slew rate dependent buffer 155 discussed above. In some embodiments, buffer 186 generates an output having imbalanced transitions. For example, low to high transitions may be faster than high to low transitions. This may be accomplished, for example, by appropriate relative sizing of output pull-down and pull-up transistors and/or including a current limiting element in the pull-down path of the buffer 186.

ESD GaN transistor 185 may have characteristics similar or identical to ESD transistors discussed elsewhere herein.

ESD events across nodes A and B, which begin with a slew rate greater than a threshold cause the input to buffer 186 to rise to a voltage high enough to cause buffer 186 to output a gate voltage for ESD transistor 185 resulting in ESD transistor 185 turning on.

The high pass filter and the buffer 186 collectively form a dv/dt detection filter configured to cause the ESD transistor 185 to turn on in response to a slew rate greater than, for example, about 1 V/ns.

Voltage events across nodes A and B, which do not include a slew rate greater than a threshold do not cause buffer 186 to output a gate voltage for ESD transistor 185 resulting in ESD transistor 185 turning on.

In some embodiments, buffer 186 is omitted, and the gate of the ESD transistor 185 is driven by the high pass filter.

Each of the circuits discussed herein include one or more inventive features. The various features of the circuits may be applied to other embodiments of circuits in combinations of features which are contemplated, but not specifically discussed for the sake of brevity.

The various aspects of the devices discussed herein may be practiced in other semiconductor technologies. For example, the various aspects of the devices discussed herein may be practiced in Silicon, Germanium, Gallium Arsenide, Silicon Carbide, Organic, and other technologies.

While various embodiments of present invention have been described, it will be apparent to those of skill in the art that many more embodiments and implementations are possible that are within the scope of this invention. Accordingly, the present invention is not to be restricted except in light of the attached claims and their equivalents.

What is claimed is:

1. A circuit, comprising:
first and second pins; and
an overvoltage protection circuit comprising a first enhancement-mode transistor, wherein the overvoltage protection circuit is disposed on a GaN-based substrate,
wherein the first enhancement mode transistor is configured to provide overvoltage protection between the first and second pins.

2. The circuit of claim 1, wherein the overvoltage protection circuit does not contain depletion-mode transistors.

3. The circuit of claim 1, wherein the overvoltage protection circuit comprises at least one diode-connected transistor disposed between the first and second pins.

4. The circuit of claim 1, wherein the overvoltage protection circuit comprises:
second and third enhancement-mode transistors, wherein a source of the second enhancement-mode transistor is coupled to a gate of the third enhancement-mode transistor; and
an electrically conductive element coupled in an electrical path between the source of the second enhancement-mode transistor and a source of the first enhancement-mode transistor, wherein the electrically conductive element comprises at least one of: a resistor, a depletion-mode transistor, a reference current sink, and a reference current source.

5. The circuit of claim 1, wherein the overvoltage protection circuit comprises:
second and third enhancement-mode transistors, wherein a source of the second enhancement-mode transistor is coupled to a gate of the third enhancement-mode transistor; and
an electrically conductive element coupled in an electrical path between the source of the second enhancement-mode transistor and the gate of the third enhancement-mode transistor, wherein the electrically conductive element comprises at least one of: a resistor, a depletion-mode transistor, a reference current sink, and a reference current source.

6. The circuit of claim 1, wherein the overvoltage protection circuit is configured to remain in an off state until a voltage potential across the first and the second pins is above a threshold voltage level.

7. The circuit of claim 1, wherein one or more diodes or diode-connected transistors are connected in series and coupled between a drain of the first enhancement-mode transistor and a gate of the first enhancement-mode transistor.

8. The circuit of claim 7, wherein an electrically conductive element is coupled in an electrical path between the gate of the first enhancement-mode transistor and a source of the first enhancement-mode transistor, wherein the electrically conductive element comprises at least one of: a resistor, a depletion-mode transistor, a reference current sink, and a reference current source.

9. The circuit of claim 1, wherein the first enhancement-mode transistor is configured to conduct a current of at least 500 mA when exposed to an overvoltage pulse.

10. The circuit of claim 1, wherein the overvoltage protection circuit comprises second and third enhancement-mode transistors, wherein a source of the third enhancement-mode transistor is connected to a gate of the second enhancement-mode transistor, and wherein a source of the second enhancement-mode transistor is connected to a gate of the first enhancement-mode transistor.

11. The circuit of claim 1, wherein, in response to a changing voltage between the first and second pins changing with a rate greater than 1V/ns, the first enhancement-mode transistor is configured to turn on so as to conduct current between the first and second pins.

12. The circuit of claim 11, further comprising a dv/dt detection filter connected between a drain of the first enhancement-mode transistor and a source of the first enhancement-mode transistor, wherein the dv/dt filter is configured to power a gate of the first enhancement-mode transistor in response to the changing voltage.

13. The circuit of claim 12, further comprising a GaN-based logic circuit connected to the dv/dt filter and coupled to a gate of the first enhancement-mode transistor, wherein the logic circuit comprises at least one of: an inverter and a buffer.

14. The circuit of claim 13, wherein the logic circuit is configured to maintain the first enhancement mode in a conductive state for at least the total duration of a rise and a fall of the changing voltage.

15. The circuit of claim 11, further comprising a second enhancement mode transistor, wherein a source of the second enhancement mode transistor is connected to a source of the first enhancement mode transistor, and wherein a drain of the second enhancement mode transistor is connected to a gate of the first enhancement mode transistor.

16. The circuit of claim 15, further comprising a dv/dt detection filter connected between a drain of the first enhancement-mode transistor and a source of the first enhancement-mode transistor, wherein the dv/dt filter is configured to power a gate of the second enhancement-mode transistor in response to the changing voltage changing with a rate less than 1V/ns.

17. The circuit of claim 16, further comprising a GaN-based logic circuit connected to the dv/dt filter and coupled to a gate of the second enhancement-mode transistor, wherein the logic circuit comprises at least one of: an inverter and buffer.

18. The circuit of claim 11, wherein a drain of the first enhancement-mode transistor is connected to the first pin and a source of the first enhancement-mode transistor is connected to the second pin.

19. The circuit of claim 11, wherein a current limiting element is disposed between the first pin and a drain of the first enhancement-mode transistor, wherein the current limiting element comprises at least one of: a resistor, a depletion mode transistor, and a current source, and wherein a source of the first enhancement-mode transistor is connected to the second pin.

20. The circuit of claim 18, wherein the current limiting element is configured to limit the current flowing therethrough in response to a voltage thereacross exceeding 10V.

21. The circuit of claim 1, wherein the first pin is connected to the gate of a power transistor and the second pin is connected to the source of the power transistor.

22. The circuit of claim 1, wherein the first pin is connected to a power supply terminal and the second pin is connected to the source of a power transistor.

23. The circuit of claim 1, wherein the first pin connected to is an input to a logic circuit and the second pin is connected to one of: a power supply terminal, and the source of a power transistor.

24. The circuit of claim 1, wherein the first pin is connected to a first power supply terminal and the second pin is connected to a second power supply terminal.

25. An electronic power conversion component comprising:
a package base; and
one or more GaN-based dies secured to the package base, wherein the GaN-based die comprises:
a first circuit comprising at least one enhancement-mode transistor; and
an overvoltage protection circuit coupled to the first circuit.

26. A method of operating a GaN-based circuit, the method comprising:
receiving a voltage greater than a threshold across two pins of the circuit; and
in response to the received voltage, turning on a GaN-based enhancement-mode transistor coupled between the two pins, such that the enhancement-mode transistor conducts current between the two pins while the voltage potential is greater than the threshold.

27. The method of claim 26, further comprising:
receiving a changing voltage between the two pins changing with a rate greater than 1V/ns; and
in response to the changing voltage, turning on the first enhancement-mode transistor so as to conduct current between the two pins.
